(19) United States
(12) Patent Application Publication
(10) Pub. No.: US 2024/0222107 A1
(43) Pub. Date: Jul. 4, 2024

(54) METHODS AND APPARATUSES FOR CARBON DEPOSITION

(71) Applicant: ASM IP Holding B.V., Almere (NL)

(72) Inventor: Varun Sharma, Helsinki (FI)

(21) Appl. No.: 18/395,861

(22) Filed: Dec. 26, 2023

Related U.S. Application Data
(60) Provisional application No. 63/477,743, filed on Dec. 29, 2022.

(51) Int. Cl. H01L 21/02; C23C 16/26; C23C 16/56

(52) U.S. Cl. CPC H01L 21/02115; C23C 16/26; C23C 16/56; H01L 21/02205; H01L 21/0228

(57) ABSTRACT

The disclosure relates to methods of depositing carbon material on a substrate. The method comprises providing a substrate in a reaction chamber and depositing material comprising metal and carbon conformally on the substrate. A halogen compound comprising a halogen and a non-halogen element is provided into the reaction chamber in a vapor phase to substantially remove the metal from the material comprising metal and carbon to form carbon material comprising primarily carbon on the substrate. The disclosure further relates to structures and electronic devices manufactured using methods disclosed herein, and to substrate processing assemblies.

### CROSS-REFERENCE TO RELATED APPLICATION(S)

This application claims the benefit of U.S. Provisional Application 63/477,743 filed on Dec. 29, 2022, the entire contents of which are incorporated herein by reference.

### FIELD

The present disclosure relates to methods and apparatuses for the manufacture of semiconductor devices. More particularly, the disclosure relates to methods and apparatuses for depositing amorphous carbon.

### BACKGROUND

Semiconductor device fabrication processes generally use advanced methods for creating fine patterns of features on a surface of a substrate. Semiconductor device function requires materials with different electrical properties in carefully controlled locations and in variable thicknesses. In addition to conductors and semiconductors, insulators are needed in many places to ascertain the correct function of the devices.

Amorphous carbon is used, for example, as photoresist for patterning, low k dielectric material, low thermal conductivity material, contact material and in masking structures, depending on the properties of the deposited amorphous carbon. To appropriately fulfil its function, amorphous carbon should have uniform properties and layer thickness. However, deposition of amorphous and highly pure carbon is very challenging, and new methods are needed in the art, to expand the use of amorphous carbon in semiconductor devices.

Any discussion, including discussion of problems and solutions, set forth in this section has been included in this disclosure solely for the purpose of providing a context for the present disclosure. Such discussion should not be taken as an admission that any or all of the information was known at the time the invention was made or otherwise constitutes prior art.

### SUMMARY

This summary is provided to introduce a selection of concepts in a simplified form. These concepts are described in further detail in the detailed description of example embodiments of the disclosure below. This summary is not intended to necessarily identify key features or essential features of the claimed subject matter, nor is it intended to be used to limit the scope of the claimed subject matter.

In an aspect, a method of depositing carbon material on a substrate is disclosed. The method comprises providing a substrate in a reaction chamber and depositing material comprising metal and carbon conformally on the substrate. A halogen compound comprising a halogen and a non-halogen element is provided into the reaction chamber in a vapor phase to substantially remove the metal from the material comprising metal and carbon to form carbon material comprising at least 75 at-% carbon on the substrate.

In some embodiments, the material comprising metal and carbon is deposited by a cyclic deposition process.

In some embodiments, the material comprising metal and carbon comprises a carbide.

In some embodiments, a metal in the material comprising metal and carbon is a transition metal. In some embodiments, the metal in the material comprising metal and carbon is selected from aluminum, titanium, iron, cobalt, nickel, niobium, molybdenum, hafnium, tantalum and tungsten. In some embodiments, the material comprising metal and carbon is selected from a group consisting of AlCₓ, TiC, TiAlₓC_{y}, FeCₓ, CoCₓ, NiCₓ, NbCₓ, MoCₓ, HfAlₓC_{y}, TaCₓ and WCₓ.

In some embodiments, the second element is selected from carbon, nitrogen, boron, phosphorus and sulfur. In some embodiments, the halogen compound is an organic halide. In some embodiments, the organic halide has a formula CₙH_{y}XₐY_{b}, wherein X and Y are independently selected from Cl, Br and I, n is 1, 2 or 3, y+a+b is 2n or 2n+2, and wherein at least one of a and b is 1 or more. In some embodiments, the organic halide is selected from CBrCl₃, CCl₄, CBr₂I₂, CCl₃I, C₂Cl₆, C₂Cl₄, C₂Cl₃Br₃, CCl₂Br₂ and CCl₂I₂.

In some embodiments, the organic halide is an acyl halide. In some embodiments, the acyl halide is selected from acyl chlorides and acyl fluorides. In some embodiments, the acyl halide is selected from a group consisting of acetyl chloride, succinyl chloride, fumaryl chloride, malonyl chloride, benzoyl chloride, terephthaloyl chloride, acetyl fluoride, succinyl fluoride, fumaryl fluoride, malonyl fluoride, terephthaloyl fluoride and benzoyl fluoride.

In some embodiments, the halogen compound is a sulfur-containing halide. In some embodiments, the halogen compound is a boron-containing halide. In some embodiments, the halogen compound is a metal halide.

In another aspect, a method of depositing carbon material on a substrate is disclosed. The method comprises providing a substrate in a reaction chamber, performing a cyclic process comprising a super-cycle, wherein the super-cycle comprises a deposition sub-cycle and an etching sub-cycle. The deposition sub-cycle comprises providing a first precursor comprising a metal into the reaction chamber in a vapor phase and providing a second precursor into the reaction chamber in a vapor phase to deposit material comprising metal and carbon conformally on the substrate. The etching sub-cycle comprises providing a halogen compound comprising a halogen and a non-halogen element into the reaction chamber in a vapor phase to substantially remove the metal from the material comprising a metal and carbon to form metal material comprising at least 75 at-% carbon on the substrate.

In some embodiments, the deposition sub-cycle is performed at least twice before performing the etching sub-cycle. In some embodiments, the super-cycle is performed at least twice.

In some embodiments, the first precursor and the second precursor are provided into the reaction chamber alternately and sequentially. In some embodiments, the method is a thermal process. In some embodiments, the method is performed at a temperature between about 200° ° C. and about 550° C.

In some embodiments, the carbon material comprises at least 95 at-% carbon. In some embodiments, the carbon material comprises less than 15 at-% hydrogen.

In a further aspect, a method of forming doped carbon material on a substrate is disclosed. The method comprises providing a substrate in a reaction chamber, depositing material comprising metal and carbon conformally on the substrate and providing a halogen compound comprising a halogen and a second element into the reaction chamber in a vapor phase to substantially remove the metal from the material comprising metal and carbon to form carbon material comprising at least 75 at-% carbon and the second element on the substrate, wherein the second element is selected from nitrogen, boron, phosphorus and sulfur.

In another aspect, a method of manufacturing a semiconductor device comprising depositing a material consisting substantially of carbon by methods of depositing carbon material disclosed herein.

In a yet further aspect, a substrate processing assembly is disclosed. The substrate processing assembly comprises a reaction chamber configured and arranged to hold a substrate, a first precursor source configured and arranged to hold and evaporate a first precursor comprising a metal, a second precursor source configured and arranged to hold and evaporate a second precursor and a halogen compound source configured and arranged to hold and evaporate a halogen compound comprising a halogen and a non-halogen element. The substrate processing assembly further comprises a controller, wherein the substrate processing assembly is constructed and arranged to provide the first precursor, the second precursor and the halogen compound into the reaction chamber in a vapor phase, and the controller is programmed to cause the system to carry out a method according to the current disclosure.

### BRIEF DESCRIPTION OF DRAWINGS

The accompanying drawings, which are included to provide a further understanding of the disclosure and constitute a part of this specification, illustrate exemplary embodiments, and together with the description help to explain the principles of the disclosure. In the drawings

FIG. 1 is a block diagram of exemplary embodiments of a method according to the current disclosure.

FIG. 2 is a block diagram of further exemplary embodiments of a method according to the current disclosure.

FIG. 3 is a schematic presentation of a deposition assembly according to the current disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure

### DETAILED DESCRIPTION

The description of exemplary embodiments of methods, structures, devices and deposition assemblies provided below is merely exemplary and is intended for purposes of illustration only. The following description is not intended to limit the scope of the disclosure or the claims. Moreover, recitation of multiple embodiments having indicated features is not intended to exclude other embodiments having additional features or other embodiments incorporating different combinations of the stated features. For example, various embodiments are set forth as exemplary embodiments and may be recited in the dependent claims. Unless otherwise noted, the exemplary embodiments or components thereof may be combined or may be applied separate from each other. The headings provided herein, if any, are for convenience only and do not necessarily affect the scope or meaning of the claimed invention.

The present disclosure generally relates to methods of depositing method of depositing carbon material on a substrate, to features, structures and semiconductor devices comprising carbon material deposited according to the current disclosure, i.e. formed using methods described herein, and to substrate processing assemblies for performing the methods according to the current disclosure. Thus, features according to the current disclosure can be used in the formation of structures and devices, such as semiconductor devices. As described in more detail below, various methods can be used to form structures suitable for forming electronic devices.

In an aspect, a method of depositing carbon material on a substrate is disclosed. The method contains two phases. First, a material comprising metal and carbon is deposited. The deposition may be a cyclic deposition process, such as atomic layer deposition (ALD) or cyclic chemical vapor deposition (CVD). The deposition may be conformal. A conformal deposition substantially follows the contours of the substrate, including any gaps or protrusions that the substrate may have. The conformality of the deposition varies according to the deposition process, such as precursors, deposition conditions and whether ALD or CVD is utilized. ALD deposition is typically more conformal than CVD, and the thickness of the deposited material may be controlled carefully. However, in some embodiments, the deposition according to the current disclosure may be non-conformal. In some embodiments, the deposition may be a gapfill deposition. By gapfill is meant the substantially complete filling of a gap or a recess on or in a substrate surface. The gapfill may be bottom-up growth or the material may grow towards the inside of the gap from sidewalls of the gap.

In the second phase of the process, a halogen compound comprising a halogen and a non-halogen element is used to remove the metal from the material comprising metal and carbon. Without limiting the current disclosure to any specific theory, the halogen compound that contacts the material comprising metal and carbon may form volatile metal halogen species leading to the removal of both the halogen and the metal from the reaction chamber. The removal of these volatile species may be enhanced by purging the reaction chamber after providing the halogen compound comprising a halogen and a non-halogen element into the reaction chamber. It may also be possible to provide the halogen compound into the reaction chamber in multiple pulses, and to purge the reaction chamber between every pulse of halogen compound.

Carbon material left behind may be very pure, and it may have good conformality, as the areas and thickness of the deposition are determined by the material comprising metal and carbon. The carbon material according to the current disclosure may be amorphous carbon.

### Reaction Chamber

The method of depositing carbon material on a substrate comprises providing a substrate in a reaction chamber. Thus, the method is performed in a space dedicated for forming materials on a substrate. The reaction chamber can form part of an atomic layer deposition (ALD) assembly. The reaction chamber can form part of a chemical vapor deposition (CVD) assembly. The deposition assembly may be an ALD or a CVD deposition assembly, but in certain process steps, MLD may also be employed in some parts of the deposition process flows.

The reaction chamber may be a single wafer reactor. Alternatively, the reaction chamber may be a batch reactor. The deposition assembly may comprise one or more multi-station deposition chambers. Various phases of method can be performed within a single reaction chamber, or they can be performed in multiple reaction chambers, such as reaction chambers of a cluster tool. In some embodiments, the method is performed in a single reaction chamber of a cluster tool, but other, preceding or subsequent, manufacturing steps of the structure or device are performed in additional reaction chambers of the same cluster tool. Optionally, an assembly including the reaction chamber can be provided with a heater to activate the reactions by elevating the temperature of one or more of the substrate and/or the reactants and/or precursors. The material according to the current disclosure may be deposited in a cross-flow reaction chamber. The material according to the current disclosure may be deposited in a showerhead-type reaction chamber.

As the method according to the current disclosure comprises a deposition phase (depositing material comprising metal and carbon) and an etching phase (metal removal from the material comprising metal and carbon), the method may be performed in one chamber or in more than one chamber. For example, the deposition phase may be performed in a first reaction chamber, and the etching phase may be performed in a second reaction chamber. The reaction chambers may be positioned in one deposition assembly, such as a cluster tool.

### Depositing Material Comprising Metal and Carbon

and depositing material comprising metal and carbon conformally on the substrate. As stated above, in some embodiments, however, the material comprising metal and carbon may be deposited non-conformally. The conformality or, conversely, gapfill behavior, of the deposition is of relevance especially for substrates comprising gaps. A gap in this disclosure is in or on a substrate. A gap is to be understood to describe a change in the surface topology of the substrate leading to some areas of the substrate surface being lower than other areas. Gaps thus include topologies in which parts of the substrate surface are lower relative to the majority of the substrate surface. These include trenches, vias, recesses, valleys, crevices and the like. Further, also areas between elevated features protruding upwards of the majority of the substrate surface form gaps. Thus, the space between adjacent fins is considered a gap.

In some embodiments, the material comprising metal and carbon is deposited by a cyclic deposition process. Generally, in cyclic deposition processes according to the current disclosure, such as atomic layer deposition (ALD) and molecular layer deposition (MLD), during each cycle, a precursor is introduced to a reaction chamber and is chemisorbed to a substrate surface (e.g., a substrate surface that may include a previously deposited material from a previous deposition cycle or other material). In some embodiments, the precursor on the substrate surface does not readily react with additional precursor (i.e., the deposition of the precursor may be a partially or fully self-limiting reaction). Thereafter, another precursor or a reactant may be introduced into the reaction chamber for use in converting the chemisorbed precursor to the desired material on the deposition surface. The second precursor or a reactant can be capable of further reaction with the precursor. Purging steps may be utilized during one or more cycles, e.g., during each step of each cycle, to remove any excess precursor from the process chamber and/or remove any excess reactant and/or reaction byproducts from the reaction chamber. Thus, in some embodiments, the cyclic deposition process comprises purging the reaction chamber after providing a precursor into the reaction chamber. In some embodiments, the cyclic deposition process comprises purging the reaction chamber after providing a first precursor into the reaction chamber. In some embodiments, the cyclic deposition process comprises purging the reaction chamber after providing a second precursor into the reaction chamber. In some embodiments, the cyclic deposition process comprises purging the reaction chamber after providing a first precursor into the reaction chamber, and after providing second precursor into the reaction. Without limiting the current disclosure to any specific theory, ALD may be slower and have more controllable layer growth speed compared to CVD. In some embodiments, the first metal precursor and the second precursor are provided into the reaction chamber alternately and sequentially. In the current disclosure, the second precursor may be plasma, such as hydrogen plasma or a combination of hydrogen and nitrogen plasma.

In the current disclosure, a first precursor may comprise a metal that participates in the formation of material comprising metal and carbon. Thus, it may be termed the first precursor, the metal precursor or the first metal precursor. In the current disclosure, the second precursor may comprise carbon and provide carbon in the material comprising metal and carbon. However, in some embodiments, the metal precursor may comprise organic portions that may also be incorporated into the material comprising metal and carbon.

CVD-type processes may be characterized by vapor deposition which is not self-limiting. They typically involve gas phase reactions between two or more precursors and/or reactants. The precursor(s) and reactant(s) can be provided simultaneously to the reaction space or substrate, or in partially or completely separated pulses. However, CVD may be performed with a single precursor, or two or more precursors that do not react with each other. The single precursor may decompose into reactive components that are deposited on the substrate surface. The decomposition may be brought about by plasma or thermal means, for example. The substrate and/or reaction space can be heated to promote the reaction between the gaseous precursor and/or reactants. In some embodiments the precursor(s) and reactant(s) are provided until a layer having a desired thickness is deposited. In some embodiments, cyclic CVD processes can be used with multiple cycles to deposit a thin film having a desired thickness. In cyclic CVD processes, the precursors and/or reactants may be provided to the reaction chamber in pulses that do not overlap, or that partially or completely overlap.

In some embodiments, the material comprising metal and carbon is deposited by a thermal process, i.e. in the absence of plasma. Thus, in some embodiments, the method is a thermal process. In some embodiments, the material comprising metal and carbon is deposited by a plasma-enhanced process, i.e. using plasma or plasma-activated species to drive the reactions between precursor molecules and/or precursor molecules and substrate surface.

The process may comprise one or more cyclic phases. In some embodiments, the process comprises or one or more acyclic (i.e. continuous) phases. In some embodiments, the deposition process comprises the continuous flow of at least one precursor. In such an embodiment, the process comprises a continuous flow of a first polymer precursor or second polymer precursor. In some embodiments, one or more of the precursors are provided in the reaction chamber continuously.

The material comprising metal and carbon according to the current disclosure can refer to material that includes a metal and carbon. The material may comprise metal carbide. In some embodiments, the material comprising metal and carbon comprises a carbide.

In some embodiments, a metal in the material comprising metal and carbon is a transition metal. The metal in the material comprising metal and carbon can be, for example, one or more of cobalt (Co), iron (Fe), molybdenum (Mo), niobium (Nb), nickel (Ni), tantalum (Ta), titanium (Ti), tungsten (W), hafnium (Hf) and aluminum (Al). Suitable ligands for the metal precursors include β-diketonates, such as acetylacetonato ligand (acac), amidinato ligands, such as N,N′-di-tert-butylacetamidinato (^{t}BuAMD) and halogens, such as chlorine (Cl) and fluorine (F). Also various heteroleptic metal precursors are known for the metals. Exemplary metal precursors for depositing material comprising metal and carbon include Co(acac)₂ for Co, Fe(^{t}BuAMD)₂ for Fe, Mo(MeCp)(CO)₂(NO) or halides, such as MoCl₅, MoCl₆ for Mo, NbCl₅ or NbF₅ for Nb and Ni(acac)₂, Ni(acac)₂(TMEDA), Ni(^{t}BuDAD)₂ or Ni(^{t}BuAMD)₂ for Ni. Further, Ta may be deposited using TaNp₃Cl₂; Ti using Ti(Np)₄, W using W(CO)(3-hexyne)₃, W(N^{t}Bu)₂(NMe₂)₂ or WCl₆, Hf using HfCl₄ and Ti using TiCl₄.

The material comprising metal and carbon may comprise one metal. The material comprising metal and carbon may comprise two metals. In some embodiments, the material comprising metal and carbon is selected from a group consisting of AlCₓ, TiCₓ, TiAlₓC_{y}, FeCₓ, CoCₓ, NiCₓ, NbCₓ, MoCₓ, HfAlₓC_{y}, TaCₓ and WCₓ. “x” and “y”, where applicable, are used to highlight the possibility non-stoichiometric proportions of the metal and carbon in the material comprising metal and carbon.

To deposit the carbon in the metal comprising metal and carbon, a second precursor may be used. This may apply especially in embodiments, in which ALD is used for deposition. For some metal precursors comprising organic ligands, a CVD process without specific carbon sources may produce a suitable material comprising metal and carbon. For example, to deposit CoCₓ, Co(acac)₂ may be used as the first precursor and n-propanol as the second precursor. To deposit FeCₓ, Fe(^{t}BuAMD)₂ may be used as the first precursor and the deposition may be brought about by H₂ plasma. MoCₓ, may be deposited using various combinations for first and second precursors. For the metalorganic Mo(MeCp)(CO)₂(NO), hydrogen plasma may be used, whereas Mo halide precursors, such as MoCl₅ may be combined with an alkylaluminum precursor as the second precursor. Suitable alkylaluminum compounds include trimethylaluminum. NiCₓ may be deposited using an organometallic precursor (such as Ni(^{t}BuDAD)₂ or Ni(^{t}BuAMD)₂) with hydrogen plasma, for example. Also an alcohol, such as a small primary alcohol, for example ethanol or n-propanol may be used. Also formic acid can be used, for example with Ni(acac)₂(TMEDA). TaCₓ and TiCₓ may be deposited using TaNp₃Cl₂ and Ti(Np)₄, respectively with hydrogen plasma. WCₓ may be deposited using W(CO)(3-hexyne)₃ or W(N^{t}Bu)₂(NMe₂)₂ and plasma (such a s a combination of nitrogen and hydrogen plasma) or a hydrazine or a derivative thereof (such as alkylhydrazine like ^{t}BuNHNH₂). Further, WCl₆ as the first precursor and an aluminum hydride derivative, such as trimethyl aluminum or AlH₂(^{t}BuNCH₂CH₂NMe₂), as a second precursor may be used. Aluminum may be combined with another metal, such as hafnium or titanium to produce HfAlₓC_{y} or TiAlₓC_{y}, respectively. A halide precursor, such as HfCl₄ or TiCl₄ may be combined with an alkylaluminum compound, such as trimethylaluminum or triethylaluminum. In the current disclosure, acac stands for acetylacetonato, AMD for amidinates, such as acetamidinato, ^{t}Bu for tert-butyl, Cp for cyclopentadienyl, Np stands for neopentyl, Me for methyl, TMEDA for N,N,N′,N′-tetraethylethylenediamine, DAD for 1,4-diaza-1,3-butadiene, ⁱPr for isopropyl and Hthd for 2,2,6,6-tetramethyl-3,5-heptanedione.

The deposition of the material comprising metal and carbon is performed at a deposition temperature. The deposition temperature may be, between about 50° C. and about 550° C. For example, when material comprising metal and carbon is deposited by a plasma-enhanced method, such as PEALD or PECVD. In plasma-enhanced processes, the deposition temperature may be between about 50° C. and about 400° C. In thermal processes (i.e. when the deposition is performed in the absence of plasma-generated reactive species), the deposition temperature may be between about 150° C. and about 550° C.

Providing a Halogen Compound into the Reaction Chamber

When material comprising metal and carbon has been deposited, a halogen compound comprising a halogen and a non-halogen element is provided into the reaction chamber in a vapor phase. The halogen compound contacts the material comprising metal and carbon to substantially remove the metal from the material comprising metal and carbon. The carbon of the material comprising metal and carbon is left on the surface of the substrate to form carbon material comprising at least 75 at-% carbon on the substrate.

The reaction chamber may be purged before the halogen compound is provided into the reaction chamber. The reaction chamber may also be purged during the deposition phase of the method, for example after providing each precursor into the reaction chamber. As used herein, the term “purge” refers to a procedure in which vapor phase precursors and/or vapor phase byproducts are removed from the substrate surface for example by evacuating the reaction chamber with a vacuum pump and/or by replacing the gas inside a reaction chamber with an inert or substantially inert gas such as argon or nitrogen. Purging may be effected between two pulses of gases which react with each other. However, purging may be effected between two pulses of gases that do not react with each other. For example, a purge, or purging may be provided between pulses of two precursors or between a precursor and a reactant. Purging may avoid or at least reduce gas-phase interactions between the two gases reacting with each other. It shall be understood that a purge can be effected either in time or in space, or both. For example, in the case of temporal purges, a purge step can be used e.g. in the temporal sequence of providing a first precursor to a reaction chamber, providing a purge gas to the reaction chamber, and providing a second precursor to the reaction chamber, wherein the substrate on which a layer is deposited does not move. For example, in the case of spatial purges, a purge step can take the following form: moving a substrate from a first location to which a first precursor is continually supplied, through a purge gas curtain or another means of separating the two spaces, to a second location to which a second precursor is continually supplied. Purging times may be, for example, from about 0.01 seconds to about 20 seconds, from about 0.05 s to about 20 s, or from about 1 s to about 20 s, or from about 0.5 s to about 10 s, or between about 1 s and about 7 seconds, such as 5 s, 6 s or 8 s. However, other purge times can be utilized if necessary, such as where highly conformal step coverage over extremely high aspect ratio structures or other structures with complex surface morphology is needed, or in specific reactor types, such as a batch reactor, may be used.

Various types of halogen compounds comprising a halogen and a non-halogen element may be used in the method according to the current disclosure. In some embodiments, the halogen compound is an organic halide. In some embodiments, the organic halide has a formula CₙH_{y}XₐY_{b}, wherein X and Y are independently selected from Cl, Br and I, n is 1, 2 or 3, y+a+b is 2n or 2n+2, and wherein at least one of a and b is 1 or more. For example, the organic halide may comprise one carbon atom and one, two, three or four halogen atoms attached to it. All the halogen atoms may be the same halogen (i.e. b=0) or different halogens, such as chlorine and bromine, chlorine and iodine or bromine and iodine may be attached to the carbon. Similarly, the organic halide may comprise two carbon atoms. Each of the carbon atoms may have at least one hydrogen replaced by a halogen. In some embodiments, each of the hydrogens in the organic halide have been replaced with a halogen (i.e. the organic halide is fully halogenated). In some embodiments, the organic halide comprises three carbon atoms. In organic halides comprising two or more carbon atoms, the halogen atoms may be distributed across all carbon atoms, or at least one carbon atom may have no halogens attached to it. In some embodiments, the organic halide is selected from CBrCl₃, CCl₄, CBr₂I₂, CCl₃I, C₂Cl₆, C₂Cl₄, C₂Cl₃Br₃, CCl₂Br₂ and CCl₂I₂. In some embodiments, the organic halide comprises a double bond. A double bond naturally reduces the maximum number of halogens in the compound by two. However, in some embodiments, it may be advantageous to use halogen compound comprising a double bond. A double bond may be more easily at least partially broken than a single bond, and the halogen compound may be more likely to contribute to the accumulation and/or repair the material comprising metal and carbon already deposited on the substrate.

In some embodiments, the organic halide is an acyl halide. The acyl halide may be selected from C2 to C8 compounds. In some embodiments, the acyl halide comprises two carbon atoms. In some embodiments, the acyl halide comprises three carbon atoms. In some embodiments, the acyl halide comprises four carbon atoms. In some embodiments, the acyl halide comprises five carbon atoms. In some embodiments, the acyl halide comprises six carbon atoms. In some embodiments, the acyl halide comprises seven carbon atoms. In some embodiments, the acyl halide comprises eight carbon atoms.

The acyl halide comprises a C2 to C8 alkyl. The alkyl may be aliphatic or aromatic. The alkyl may be saturated or unsaturated, linear or branched, cyclic or acyclic. In some embodiments, the alkyl is an unsubstituted hydrocarbon, i.e. it comprises only carbon and hydrogen. In some embodiments, the alkyl is a substituted or a functionalized hydrocarbon. For example, the hydrocarbon may be a hydroxylated hydrocarbon, an alcohol, or a carboxylic acid. The hydrocarbon may be an ester, a ketone or an aldehyde. The hydrocarbon may comprise an amine or an imine. The acyl halide may comprise one or more acyl halide groups. In some embodiments, the acyl halide is selected from acyl chlorides and acyl fluorides. In some embodiments, the acyl halide is selected from a group consisting of acetyl chloride, succinyl chloride, fumaryl chloride, malonyl chloride, benzoyl chloride, terephthaloyl chloride, acetyl fluoride, succinyl fluoride, fumaryl fluoride, malonyl fluoride, terephthaloyl fluoride and benzoyl fluoride.

In some embodiments, the halogen compound comprising a halogen and a non-halogen element is a halogen-containing β-diketone, such as hexafluoroacetylacetone (Hhfac).

In some embodiments, the halogen compound is a non-carbon halide compound. The halogen compound may comprise, for example, sulfur, boron, nitrogen or phosphorus. In some embodiments, the halogen compound comprising a halogen and a non-halogen element is a sulfur-containing halide. Examples of sulfur-containing halides are SOCl₂ and SO₂Cl₂, SCl, S₂Cl₂, SCl₂, SF₄ and SF₆. In some embodiments, the etchant is a boron halide. For example, boron halides of formula BXₐY₃₋ₐ, wherein X and Y are halogens and a is 1, 2 or 3 may be used. Examples of such compounds include such as BF₃, BCl₃, BClF₂ or BFCl₂. In some embodiments, one of X and Y may be an organic ligand, such as an β-diketonate, and the halogen compound for example (acac)BF₂. Boron halides may etch, for example, MoCₓ, NbCₓ, NiCₓ, TaCₓ, TiCₓ, WCₓ, HfAlₓC_{y} and TiAlₓC_{y}. In some embodiments, the boron-containing halogen compound may be an adduct of a boron halide. The adduct ligand may be selected from, for example, an ether, a thioether, an amine and a phosphine. Examples of boron halide adducts include BFCl₂:OEt₂ and BFCl₂:SMe₂, wherein Et stands for ethyl and Me for methyl. In some embodiments, the etchant is a nitrosyl halide. In some embodiments, the nitrosyl halide is selected from a group consisting of nitrosyl fluoride (NOF) and nitrosyl chloride (NOCl). In some embodiments, the non-carbon halide is a metal halide. In some embodiments, the etchant is a molybdenum halide, such as molybdenum chloride, for example MoCl₅ or MoCl₆, or a molybdenum fluoride, for example MoF₅ or MoF₆. Also a molybdenum oxyhalide, having a general formula of MoOₐX_{b} can be used. In some embodiments, the etchant is a niobium halide, such as niobium chloride, for example NbCl₅, or a niobium fluoride, such as NbF₅. In some embodiments, the etchant is a tantalum halide, such as tantalum chloride, for example TaCl₅, a tantalum fluoride, such as TaF₅, tantalum bromide, such as TaBr₅ or a tantalum iodide, such as TaI₅. In some embodiments, the etchant is a tungsten halide, such as tungsten chloride, for example WCl₅, WCl₆, or a tungsten fluoride, such as WF₆. For example, MoCₓ, NbCₓ, NiCₓ, TaCₓ, TiCₓ, WCₓ, HfAlₓC_{y} and TiAlₓC_{y} can be etched by the metal halides described above.

In some embodiments, the material comprising metal and carbon is etched with a single halogen compound comprising a halogen and a non-halogen element. The single halogen compound can be any of the compounds and groups of compounds listed above. In some embodiments, the material comprising metal and carbon is etched by contacting the material comprising metal and carbon sequentially with two different etching compounds, at least one of them being a halogen compound (“two-phase scheme”). Thus, etching may be performed as a cyclic etching process. In some embodiments, the etching is atomic layer etching (ALEt).

For example, material comprising metal and carbon may be first contacted with halogen compounds such as HF or HCl (being first etching compounds) and thereafter the material comprising metal and carbon can be contacted with a second etching compound that is a β-diketone, such as acetylacetone (Hacac) or Hhfac. In some embodiments, the material comprising metal and carbon can be first contacted with an oxidant, such as oxygen or ozone, and thereafter with a β-diketonate, such as Hhfac. Exemplary materials comprising metal and carbon that may be etched with the two-phase schemes detailed above are CoCₓ and FeCₓ. Further examples of the two-phase scheme are etching by first contacting the material comprising metal and carbon with two different halogen compounds sequentially. As the first halogen compound, NbCl₅, HF, SF₄, or NbF₅, Cl₂, SOCl₂, BCl₃, BF₃ may be used, and as a second halogen compound, Cl₂, SOCl₂, SO₂Cl₂, CCl₃Br, BCl₃, BF₃ may be used. Materials that can be etched by the second two-phase scheme are MoCₓ, NbCₓ, NiCₓ, TaCₓ, TiCₓ, WCₓ, HfAlₓC_{y} and TiAlₓC_{y}. Especially for MoCₓ, Cl₂ may be preferred as the second halogen compound. Although the two phases of providing etching compounds may be separate, they may overlap. Especially, if one of the etching compounds is molecular halogen, such as Cl₂ or Br₂, it may be advantageous to provide the two etching compounds into the reaction chamber at least partially simultaneously. This may influence the etching rate, and also the presence of non-halogen elements in vapor phase during etching may allow repairing cavities that may be formed in the deposited material as metal is being removed. Thus, using etching compounds that contain also non-halogen compounds may have benefits over using only halogen in etching. The combination of compounds that consist of halogen and compounds that contain additional elements may have the advantage of efficient etching while forming good-quality carbon material, i.e., carbon material comprising less cavities.

Further, cavity formation may allow halogen compounds to reach the substrate material under the material comprising metal and carbon. This may lead into unwanted etching of the underlying material. Therefore, providing non-halogen elements that may fill in any voids or cavities formed during etching may have the advantage of protecting the underlying substrate from etching. Similar problems using only halogen-containing molecules arise in the presence of material having grain boundaries. Grain boundaries may form entry sites for halogens to reach the substrate below the material comprising metal and carbon. Using halogens, such as Cl₂ or Br₂ alone in etching may be impractical, as the gases are high-vapor pressure toxic gases. Replacing them with less aggressive chemicals could therefore be advantageous.

In an alternative aspect, the halogen compound may be substituted by another type of an etching compound. For example, a carboxylic acid or a β-diketone may be used as an etchant. For example, MoCₓ or FeCₓ could be etched by providing formic acid, Hacac or Hthd (2,2,6,6-tetramethyl-3,5-heptanedione) into the reaction chamber.

As is known to those skilled in the art, not all halogen compounds comprising a halogen and a non-halogen element can etch all materials comprising metal and carbon. Without limiting the current disclosure to any specific theory, efficient etching may require a volatile reaction product from the reaction between the material being etched and the etchant (the halogen compound). Thus, for example, TiCₓ may be etched with F-containing halogen compounds as TiF₄ may be suitably volatilized.

The etching is performed in an etching temperature. The etching temperature may be the same as the deposition temperature. Alternatively, the etching temperature may be different than the deposition temperature. The etching temperature may be lower than the deposition temperature. In some embodiments, the etching temperature is higher than the deposition temperature. In some embodiments, the etching temperature is from about 200° C. to about 550° C. Without limiting the current disclosure to any specific theory, a higher temperature may increase the rate and/or efficiency of etching. In some embodiments, the method is performed at a temperature between about 200° C. and about 550° C. In some embodiments, the process is performed at a temperature between about 300° C. and about 550° C. or at a temperature between about 400° C. and about 550° C. In some embodiments, the process is performed at a temperature between about 200° C. and about 450° C. or at a temperature between about 200° C. and about 300° C. or at a temperature between about 200° C. and about 250° C.

In some embodiments, etching may be performed in the presence of reactive species generated from plasma. For example, direct plasma, i.e. configuration in which plasma is generated in the reaction chamber, can be used. Also, remote plasma may be used. In remote plasma, plasma is generated outside the reaction chamber. When using plasma, oxygen-free halogen compounds comprising a halogen and a non-halogen element are used to avoid removing carbon from the material comprising metal and carbon. Also, metal halides are not used when plasma is used during etching. For example, halogen species, such as nitrogen-containing halogen compounds, such as NCl₃, sulfur-containing halogen compounds, such as SCl, S₂Cl₂, SCl₂, SF₄ and SF₆, boron-containing halogen compounds, such as BCl₃, BClF₂ or BFCl₂, and alkyl halides, such as CCl₄, are examples of suitable halogen compounds for the methods according to the current disclosure. Examples of plasmas that may be used are argon, nitrogen or noble gases. In some embodiments, plasma is generated from a noble gas-containing gas. For example, noble gas may be selected from helium, neon, argon and krypton. In some embodiments, the noble gas is not argon. In some embodiments, the noble gas is helium. In some embodiments, the plasma is generated from a gas comprising about 1% or less, such as 0.5% argon.

For thermal etching (i.e. etching when no plasma is used), the temperature during etching may be at least about 250° C., such as about 400° C. or about 500° ° C. In embodiments, in which plasma is used during etching, lower temperatures, such as temperatures of at least 150° ° C. may be used. For example, in embodiments comprising plasma etching the temperature during etching may be from about 150° C. to about 550° C., such as from about 150° C. to about 350° C., or from about 150° C. to about 250° C.

In some embodiments, the plasma power is from about 20 W to about 500 W. In some embodiments, plasma is generated from argon-containing gas, and the plasma power is at most about 50 W. In some embodiments, plasma is generated from argon-containing gas, and the plasma power is from about 20 W to about 50 W, such as about 30 W or about 40 W. In some embodiments, plasma is generated from helium- or nitrogen-containing gas, which optionally does not contain argon, and the plasma power is from about 20 W to about 500 W, such as from about 50 W to about 300 W, or from about 50 W to about 200 W, or from about 50 W to about 200 W, such as about 100 W or about 150 W or about 250 W.

Deposition Phase Vs. Super-Cycle

The methods according to the current disclosure may be performed in different configurations. It is possible to first deposit a desired thickness of material comprising metal and carbon, and after the deposition is complete, to etch the metal with the halogen compound comprising a halogen and a non-halogen element. This may be termed a direct configuration of forming carbon material. Alternatively, the deposition and etching can be each performed multiple times, such that only a portion of the intended thickness of the material comprising metal and carbon is deposited before the material is etched. After etching, the deposition may be performed again. This configuration may be termed the super-cycle configuration.

In one aspect, the method of depositing carbon material on a substrate according to the current disclosure comprises providing a substrate in a reaction chamber and performing a cyclic process comprising a super-cycle. The super-cycle comprises a deposition sub-cycle and an etching sub-cycle. The deposition sub-cycle comprises providing a first precursor comprising a metal into the reaction chamber in a vapor phase and providing a second precursor into the reaction chamber in a vapor phase to deposit material comprising metal and carbon conformally on the substrate. The etching sub-cycle comprises providing a halogen compound comprising a halogen and a non-halogen element into the reaction chamber in a vapor phase to substantially remove the metal from the material comprising a metal and carbon to form metal material comprising at least 75 at-% carbon on the substrate. Optionally, the etching sub-cycle may comprise providing two different etching compounds, at least one of them being a halogen compound into the reaction chamber sequentially. In some embodiments, the two etching compounds are provided into the reaction chamber alternately and sequentially.

In some embodiments, the deposition sub-cycle is performed at least twice before performing the etching sub-cycle. In some embodiments, the super-cycle is performed at least twice. The thickness of the material comprising metal and carbon can be regulated by adjusting the number of deposition sub-cycles. Without limiting the current disclosure to any specific theory, the combination of material comprising metal and carbon and etching compound(s), such as halogen compound comprising a halogen and a non-halogen element, may influence the selected number of each sub-cycle. Different materials and halogen compounds may vary in how thick a layer of material comprising metal and carbon can be etched by the halogen compound. Thus, the needed uniformity or other properties of the composition of the formed carbon material may influence the selection of ratio between deposition sub-cycle and etching sub-cycle. For example, the ratio between the number of deposition subcycles and etching subcycles may vary from about 50:1 to about 1:1.

The number of deposition sub-cycles and etching sub-cycles varies from embodiment to embodiment. For example, different material comprising metal and carbon have different growth speeds. Thus, the cycle number for achieving target layer thickness may vary. In a non-limiting exemplary method, for depositing about 5 nm of TiC by using TiCl₄ and Al(^{t}Bu)₃ as precursors at about 350° C., from about 50 to 100 deposition cycles may be needed. Ti was then removed by using from about 10 to about 50 cycles of Cl₂, SOCl₂, CCl₃Br at a temperature of about 350° C. to about 500° C. The thickness of the formed carbon material was about 5 nm.

In some embodiments, at least 20 nm of material comprising metal and carbon may be etched to form carbon material. In some embodiments, at least 30 nm of material comprising metal and carbon may be etched to form carbon material. For many applications, this may be a sufficient thickness of the carbon material, and therefore a super-cycle configuration may not be necessary. However, in some embodiments, the etching thickness may be less than 20 nm. Further, for some applications, thicker carbon material layers are needed, and therefore, it may be necessary to use the super-cycle configuration.

### Carbon Material

Carbon material formed by the methods according to the current disclosure is primarily carbon. The material may be termed amorphous carbon, although the exact properties of the material may vary according to the deposition and etching conditions. For example, the hybridization in the material may deviate from the ideal sp³ hybridization, and both sp and sp² hybridization may exist in the carbon material while it still retains its amorphous characteristics.

By the carbon material formed by the methods according to the current disclosure comprising primarily of carbon is herein meant that the carbon material comprises at least about 75 a-% carbon. In some embodiments, the carbon material comprises at least about 80 at-% carbon. In some embodiments, the carbon material comprises at least about 85 at-% carbon. In some embodiments, the carbon material comprises at least about 90 at-% carbon. In some embodiments, the carbon material comprises at least about 95 at-% carbon.

The carbon material may comprise other elements than carbon. For example, carbon material may comprise hydrogen. In some embodiments, the carbon material comprises less than about 0.5 at-% hydrogen. In some embodiments, the carbon material comprises less than about 1 at-% hydrogen. In some embodiments, the carbon material comprises less than about 3 at-% hydrogen. In some embodiments, the carbon material comprises less than about 5 at-% hydrogen. In some embodiments, the carbon material comprises less than about 10 at-% hydrogen. In some embodiments, the carbon material comprises less than about 15 at-% hydrogen.

Carbon material may comprise additional elements that may be derived from the etching compounds, such as halogen compounds. Such material may be termed doped carbon material. Accordingly, in a further aspect, a method of forming doped carbon material on a substrate is disclosed. The method comprises providing a substrate in a reaction chamber, depositing material comprising metal and carbon conformally on the substrate and providing a halogen compound comprising a halogen and a second element into the reaction chamber in a vapor phase to substantially remove the metal from the material comprising metal and carbon, to form carbon material comprising at least 75 at-% carbon and the second element on the substrate, wherein the second element is selected from nitrogen, boron, phosphorus and sulfur.

The carbon material may comprise nitrogen. Without limiting the current disclosure to any specific theory, nitrogen may be derived from one of the precursors used to deposit the material comprising metal and carbon, or from an etching compound, such as halogen compound comprising a halogen and a non-halogen element. In some embodiments, the carbon material comprises at most about 10 at-% nitrogen. In some embodiments, the carbon material comprises at most about 7 at-% nitrogen. In some embodiments, the carbon material comprises at most about 5 at-% nitrogen. In some embodiments, the carbon material comprises at most about 3 at-% nitrogen.

The carbon material may comprise sulfur. Without limiting the current disclosure to any specific theory, sulfur may be derived from one of the precursors used to deposit the material comprising metal and carbon, or from an etching compound, such as halogen compound comprising a halogen and a non-halogen element. In some embodiments, the carbon material comprises at most about 8 at-% sulfur. In some embodiments, the carbon material comprises at most about 6 at-% sulfur. In some embodiments, the carbon material comprises at most about 5 at-% sulfur. In some embodiments, the carbon material comprises at most about 2 at-% sulfur.

The carbon material may comprise boron. Without limiting the current disclosure to any specific theory, boron may be derived from one of the precursors used to deposit the material comprising metal and carbon, or from an etching compound, such as halogen compound comprising a halogen and a non-halogen element. In some embodiments, the carbon material comprises at most about 8 at-% boron. In some embodiments, the carbon material comprises at most about 6 at-% boron. In some embodiments, the carbon material comprises at most about 5 at-% boron. In some embodiments, the carbon material comprises at most about 2 at-% boron.

The carbon material may comprise phosphorus. Without limiting the current disclosure to any specific theory, phosphorus may be derived from one of the precursors used to deposit the material comprising metal and carbon, or from an etching compound, such as halogen compound comprising a halogen and a non-halogen element. In some embodiments, the carbon material comprises at most about 8 at-% phosphorus. In some embodiments, the carbon material comprises at most about 6 at-% phosphorus. In some embodiments, the carbon material comprises at most about 5 at-% phosphorus. In some embodiments, the carbon material comprises at most about 2 at-% phosphorus.

In accordance with further embodiments of the disclosure, a structure is provided. The structure can be formed according to a method as set forth herein. In accordance with further examples of the disclosure, a device comprises or is formed using a structure as described herein. In accordance with yet additional examples of the disclosure, a deposition assembly constructed and arranged to perform a method and/or to form a structure as described herein is provided.

In another aspect, a method of manufacturing a semiconductor device comprising depositing a material consisting substantially of carbon by methods of depositing carbon material disclosed herein.

In a further aspect, a substrate processing assembly is disclosed. The substrate processing assembly comprises a reaction chamber configured and arranged to hold a substrate, a first precursor source configured and arranged to hold and evaporate a first precursor comprising a metal, a second precursor source configured and arranged to hold and evaporate a second precursor and a halogen compound source configured and arranged to hold and evaporate a halogen compound comprising a halogen and a non-halogen element. The substrate processing assembly further comprises a controller, wherein the substrate processing assembly is constructed and arranged to provide the first precursor, the second precursor and the halogen compound into the reaction chamber in a vapor phase, and the controller is programmed to cause the system to carry out a method according to the current disclosure.

### DRAWINGS

The disclosure is further explained by the following exemplary embodiments depicted in the drawings. The illustrations presented herein are not meant to be actual views of any particular material, structure, device or an apparatus, but are merely schematic representations to describe embodiments of the current disclosure. It will be appreciated that elements in the figures are illustrated for simplicity and clarity and have not necessarily been drawn to scale. For example, the dimensions of some of the elements, such as thicknesses of material layers, in the figures may be exaggerated relative to other elements to help improve the understanding of illustrated embodiments of the present disclosure. The structures and devices depicted in the drawings may contain additional elements and details, which may be omitted for clarity.

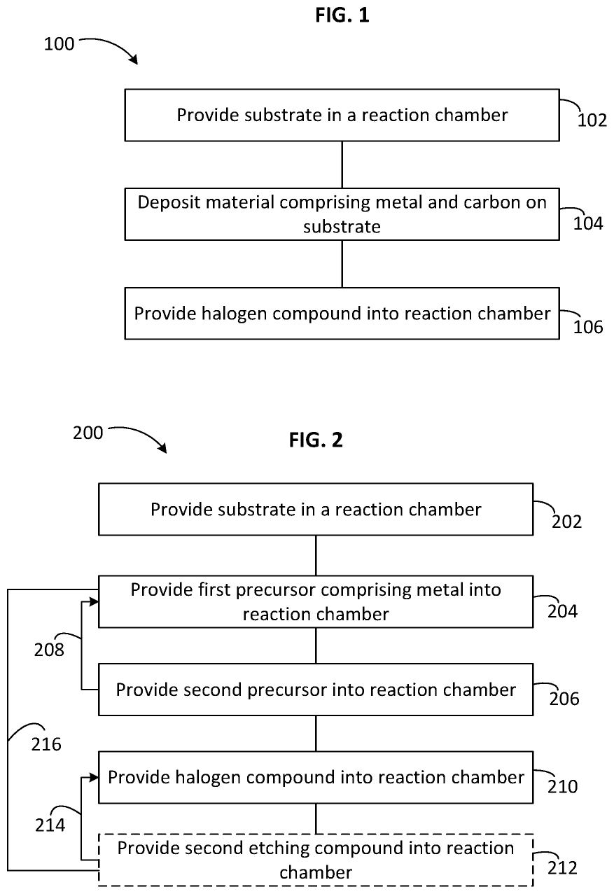

FIG. 1 is a block diagram of an exemplary embodiment of a method 100. In the first phase 102, a substrate is provided into a reaction chamber. A substrate according to the current disclosure may comprise, for example, an oxide, such as silicon oxide (for example thermal silicon oxide or native silicon oxide), aluminum oxide, or a transition metal oxide, such as hafnium oxide. A substrate may comprise a nitride, such as silicon nitride or titanium nitride, a metal, such as copper, cobalt or tungsten, chalcogenide material, such as molybdenum sulfide. The formed carbon material may form layers that can be used in the manufacture of electronic devices. Depending on the application in question, the properties of the carbon material may differ. The properties may be influenced by, for example, selection of precursors used for depositing material comprising metal and carbon, deposition conditions, choice of halogen compound comprising a halogen and a non-halogen element, as well as by the etching conditions. Further, post-deposition treatments may be employed to amend the properties of the carbon material. Layers of different thicknesses may be formed by depositing layers of material comprising metal and carbon having different thicknesses.

The reaction chamber can form part of a substrate processing assembly that is an atomic layer deposition (ALD) assembly. The reaction chamber can form part of a substrate processing assembly that is a chemical vapor deposition (CVD) assembly. The reaction chamber may be a single wafer reactor. Alternatively, the reaction chamber may be a batch reactor. The substrate processing assembly may comprise one or more multi-station deposition chambers. Various phases of method 100 can be performed within a single reaction chamber or they can be performed in multiple reaction chambers, such as reaction chambers of a cluster tool. In some embodiments, the method 100 is performed in a single reaction chamber of a cluster tool, but other, preceding or subsequent, manufacturing steps of the structure or device are performed in additional reaction chambers of the same cluster tool. Optionally, a substrate processing assembly including the reaction chamber can be provided with a heater to activate the reactions by elevating the temperature of one or more of the substrate and/or the reactants and/or precursors. The carbon material according to the current disclosure may be formed in a cross-flow reaction chamber. The carbon material according to the current disclosure may be formed in a shower head-type reaction chamber.

During phase 102, the substrate can be brought to a desired temperature and pressure in the reaction chamber can be adjusted for performing the method according to the current disclosure. A temperature (for example temperature of a substrate or a substrate support) within a reaction chamber can be, for example, from about 150° C. to about 550° C., from about 150° C. to about 400° C., from about 200° C. to about 350° C. or from about 150° ° C. to about 350° C. A pressure within the reaction chamber can be less than 500 Torr, or less than 100 Torr, or less than 50 Torr, or less than 20 Torr. For example, a pressure in the reaction chamber may be about 40 Torr, about 30 Torr, about 15 Torr, about 5 Torr, about 3 Torr, about 1 Torr or about 0.1 Torr. Different pressure may be used for different process steps.

At phase 104, material comprising metal and carbon is deposited on the substrate. The deposition process may comprise providing a first precursor comprising a metal into the reaction chamber and providing a second precursor into the reaction chamber. The material comprising metal and carbon may be deposited by a CVD process. The deposition method may be a cyclic deposition method. The material comprising metal and carbon may be deposited by a cyclic deposition process, in which the first precursor and the second precursor are provided into the reaction chamber sequentially. In some embodiments, the first precursor and the second precursor are provided into the reaction chamber alternately and sequentially. The material comprising metal and carbon may be deposited by an ALD process. The resulting material comprising metal and carbon may be any of the materials described herein. The material comprising metal and carbon may be a metal carbide.

The duration of providing first precursor into the reaction chamber (first precursor pulse time) may be, for example, from about 0.1 to about 15 seconds, from about 0.5 to about 10 seconds, from about 0.5 to about 5 seconds, or from about 0.5 to about 3 seconds. For example, the first precursor pulse time may be about 0.5 seconds, 1 second, 1.5 seconds, 2 seconds, 3 seconds, 3.5 seconds, 5 seconds, 7 seconds, or 10 seconds. In some embodiments, the first precursor pulse time may be shorter than 25 s, shorter than 15 s, shorter than 8 s, shorter than 5 s, or shorter than 2 s. The duration depends on the precursor used, and on the application, for example. In some embodiments, a saturating pulsing is used. In some embodiments, a non-saturating pulsing regime is used. Without limiting the current disclosure to any specific theory, first precursor may chemisorb on the substrate during providing first precursor into the reaction chamber. Alternatively or in addition, the first precursor may react in the gas phase during, for example, a CVD deposition process.

The second precursor is also provided into the reaction chamber at phase 104. It may react with the first precursor comprising a metal, or its derivate species, to form material comprising metal and carbon. The first precursor may either be chemisorbed on the substrate surface, or in the gas phase, depending on how the method according to the current disclosure is performed. The duration of providing second precursor in the reaction chamber (second precursor pulse time) may be, for example from about 0.1 to about 15 seconds, from about 0.5 to about 10 seconds, from about 0.5 to about 5 seconds, or from about 0.5 to about 3 seconds. The duration depends on the second precursor, the first precursor used, and on the application, for example. In some embodiments, the second precursor pulse time may be shorter than 25 s, shorter than 15 s, shorter than 8 s, shorter than 5 s, or shorter than 2 s.

Providing the first precursor and the second precursor into the reaction chamber may define a deposition cycle. The deposition cycle may be repeated. The thickness of the deposited material comprising metal and carbon may be regulated by adjusting the number of deposition cycles. The deposition cycle may be repeated until a desired thickness of material comprising metal and carbon is achieved. For example, about 50, 100, 200, 300, 400, 500, 700, 800, 1,000, 1,200, 1,500 or 2,000 deposition cycles may be performed.

In some embodiments, first precursor is heated before providing it into the reaction chamber. In some embodiments, second precursor is heated before providing it to the reaction chamber. In some embodiments, the first precursor is kept in ambient temperature before providing it to the reaction chamber. In some embodiments, the second precursor is kept in ambient temperature before providing it to the reaction chamber. Providing the second precursor into the reaction chamber may comprise providing reactive species into the reaction chamber. The reactive species may be generated from a plasma.

After the material comprising metal and carbon has been deposited on the substrate, a halogen compound comprising a halogen and a non-halogen element is provided into the reaction chamber at phase 106. Providing a halogen compound into the reaction chamber removes metal from the material comprising metal and carbon, leaving primarily carbon on the substrate, thereby forming carbon material. Carbon material is formed in areas in which the material comprising metal and carbon was deposited. Thus, carbon material may be deposited conformally, if the material comprising metal and carbon was deposited conformally. In the embodiment of FIG. 1, the deposition is a direct configuration of the method according to the current disclosure in which single deposition—which may be cyclic deposition—is performed, and metal from the deposited material comprising metal and carbon is etched after the deposition has been completed.

The method of FIG. 1 may comprise one or more purge. The reaction chamber may be purged, for example, after providing each reactant and/or precursor into the reaction chamber. Thus, the reaction chamber may be purged after providing the first precursor into the reaction chamber or after providing the second precursor into the reaction chamber or after providing a halogen compound comprising a halogen and a non-halogen element into the reaction chamber. The reaction chamber may be purged after providing the first precursor into the reaction chamber and after providing the second precursor into the reaction chamber and after providing a halogen compound into the reaction chamber.

FIG. 2 illustrates another embodiment of the method 200 according to the current disclosure, and describes the deposition of material comprising metal and carbon in more detail. It is emphasized that the features of individual process phases in FIGS. 1 and 2 are interchangeable. In phase 202, substrate is provided in the reaction chamber as illustrated in phase 102 of FIG. 1. Providing first precursor comprising metal into the reaction chamber at phase 204 and providing second precursor into the reaction chamber at phase 206 are performed as explained above for FIG. 1.

The embodiment of FIG. 2 is an example of a super-cycle configuration of the method according to the current disclosure. Depositing material comprising metal and carbon is performed in a deposition sub-cycle 208, whereas metal is etched from the material comprising metal and carbon in an etching sub-cycle 214. Each of these sub-cycles can be performed a predetermined number of times, defining a super-cycle 216, which may be performed a predetermined number of times. Such a super-cycle configuration may be advantageous in applications in which forming carbon material in a direct configuration would not produce desired properties. For example, for thick carbon material layers, or in embodiments in which a gap is filled with the carbon material, a super-cycle configuration may be selected.

Although illustrated in FIG. 2 as two separate phases, providing the first precursor into the reaction chamber 204 and providing the second precursor into the reaction chamber 206 may in fact overlap. In some embodiments, phases 204 and 206 are separate as illustrated, but they can be performed in any order. Phases 204 and 206 may define a deposition cycle 208, which, in the embodiment of FIG. 2 is a deposition sub-cycle, resulting in the deposition of material comprising metal and carbon on the substrate. In some embodiments, the two phases of deposition, namely providing the first precursor and the second precursor in the reaction chamber (204 and 206), may be repeated (loop 208). Such embodiments contain several deposition sub-cycles. The thickness of the deposited material comprising metal and carbon may be regulated by adjusting the number of deposition cycles. The deposition sub-cycle (loop 208) may be repeated until a predetermined thickness of material comprising metal and carbon is achieved, after which the etching sub-cycle is initiated. For example, about 5, 10, 30, 50, 100, 200, 300, 400, 500, 700, 800 or 1,000 deposition sub-cycles 208 may be performed before an etching sub-cycle starts.

The etching sub-cycle comprises providing a halogen compound comprising a halogen and a non-halogen element into the reaction chamber 210. In some embodiments, an etching sub-cycle consists of providing a halogen compound comprising a halogen and a non-halogen element into the reaction chamber 210. In some embodiments, an etching sub-cycle comprises providing a halogen compound into the reaction chamber 210 and purging the reaction chamber. In some embodiments, an etching sub-cycle comprises providing a halogen compound comprising a halogen and a non-halogen element into the reaction chamber 210 and providing a second etching compound into the reaction chamber 212. Providing a second etching compound into the reaction chamber 212 is optional (indicated by the hatched outline of phase 212 in FIG. 2). In some embodiments, in which phase 212 is performed, providing the halogen compound comprising a halogen and a non-halogen element 210 and providing the second etching compound 212 into the reaction chamber may be repeated (loop 214). The etching sub-cycle may thus comprise providing a halogen compound into the reaction chamber one or more times. The etching sub-cycle may comprise providing a halogen compound into the reaction chamber 210 one or more times and purging the reaction chamber after at least one of the times a halogen compound is provided into the reaction chamber (not shown in FIG. 2). In some embodiments, the reaction chamber is purged substantially after every time a halogen compound is provided into the reaction chamber. Providing a halogen compound into the reaction chamber repeatedly and purging the reaction chamber after substantially every time a halogen compound is provided into the reaction chamber may have the advantage of removing reaction products, such as volatile metal halides, from the reaction chamber. This may promote etching reactions and/or reduce the precipitation of the volatile metal halides on the substrate.

In embodiments in which no second etching compound is provided into the reaction chamber, the super-cycle loop 216 returns to providing the first precursor 204 after providing the halogen compound comprising a halogen and a non-halogen element into the reaction chamber 210. In embodiments in which a second etching compound is provided into the reaction chamber 212, the super-cycle loop 216 returns to providing the first precursor 204 after providing the second etching compound into the reaction chamber 212, as shown in FIG. 2. It should be understood that although the loop 216 returns to phase 204 in FIG. 2, the deposition sub-cycle 208 may be initiated with providing the second precursor into the reaction chamber 206, in which case the super-cycle loop 216 returns to phase 206. In other words, the super-cycle returns to the first phase of the deposition sub-cycle, whatever phase it may be. In some embodiments, the deposition sub-cycle 208 begins with a purge. Purge phases are not indicated in FIGS. 1 and 2, as they may be performed in various points during the process, and including them in the method may be determined on a case-by-case basis.

The method according to the current disclosure was tested by depositing material comprising titanium, aluminum and carbon on a native oxide substrate. The titanium and carbon containing material, that formed a conformal layer, was deposited using TiCl₄ and either Al[iPr]₃ or Al[^{t}Bu]₃ as precursors at a temperature of about 400° C. This material comprising metal and carbon was etched using CCl₃Br at a temperature of 470° C. The carbon material on the substrate surface comprised more than 95 at-% carbon as measured by X-ray photoelectron spectroscopy. The carbon material did not contain detectable amounts of metals or hydrogen, and less than 2 at-% chlorine, bromine and oxygen. Without limiting the current disclosure to any specific theory, using a halogenated hydrocarbon as the halogen compound may have the advantage of repairing the carbon material during etching. Thus, the carbon from the halogen compound may be left on the surface while metal halide vaporizes.

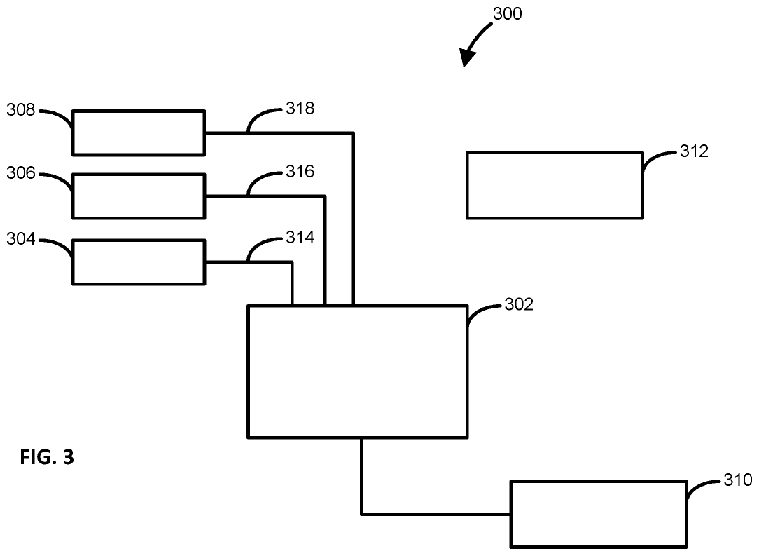

FIG. 3 illustrates a substrate processing assembly 300 according to the current disclosure in a schematic manner. Substrate processing assembly 300 can be used to perform a method as described herein and/or to form a layer, a structure or a device, or a portion thereof as described herein.

In the illustrated example, substrate processing assembly 300 includes one or more reaction chambers 302, a first precursor source 304, a second precursor source 306, a halogen compound source 308, an exhaust source 310, and a controller 312. The substrate processing assembly 300 may comprise one or more additional gas sources (not shown), such as a second etching compound source, an inert gas source, a carrier gas source and/or a purge gas source. Also, in case the material comprising metal and carbon comprises more than one metal, the substrate processing assembly 300 may further comprise additional precursor and/or reactant sources.

Reaction chamber 302 can include any suitable reaction chamber, such as an ALD or CVD reaction chamber as described herein. In some embodiments, the deposition of material comprising metal and carbon and etching with a halogen compound comprising a halogen and a non-halogen element are performed in different reaction chambers. For example, the different reaction chambers may be two processing stations in a multi-station processing chamber.

The first precursor source 304 can include a vessel and a first precursor comprising a metal as described herein—alone or mixed with one or more carrier (e.g., inert) gases. A second precursor source 306 can include a vessel and a second precursor as described herein—alone or mixed with one or more carrier gases. The halogen compound source 308 can include a vessel and a halogen compound comprising a halogen and a non-halogen element as described herein—alone or mixed with one or more carrier gases. Although illustrated with three sources, such as source vessels 304, 306 and 308, substrate processing assembly 300 can include any suitable number of sources. Sources 304, 306 and 308 can be coupled to reaction chamber 302 via lines 314, 316 and 318, which can each include flow controllers, valves, heaters, and the like. In some embodiments, the first precursor in the first precursor source 304 and/or the second precursor in the second precursor source 306 and/or the halogen compound comprising a halogen and a non-halogen element in the halogen compound source 306 may be heated. In some embodiments, the substrate processing assembly comprises a plasma generator. In some embodiments, the substrate processing assembly is configured and arranged to generate direct plasma. In some embodiments, the substrate processing assembly is configured and arranged to generate remote plasma. In embodiments in which the substrate processing assembly is configured and arranged to generate plasma, the material comprising metal and carbon can be deposited using PEALD or PECVD.

### Exhaust Source 310 can Include One or More Vacuum Pumps.

Controller 312 includes electronic circuitry and software to selectively operate valves, manifolds, heaters, pumps and other components included in the substrate processing assembly 300. Such circuitry and components operate to introduce precursors, other optional reactants and purge gases from the respective sources. Controller 312 can control timing of gas pulse sequences, temperature of the substrate and/or reaction chamber 302, pressure within the reaction chamber 302, and various other operations to provide proper operation of the substrate processing assembly 300. Controller 312 can include control software to electrically or pneumatically control valves to control flow of precursors, reactants, etching compounds and purge gases into and out of the reaction chamber 302. Controller 312 can include modules such as a software or hardware component, which performs certain tasks. A module may be configured to reside on the addressable storage medium of the control system and be configured to execute one or more processes.

Other configurations of substrate processing assembly 300 are possible, including different numbers and kinds of precursor and reactant sources. Further, it will be appreciated that there are many arrangements of valves, conduits, precursor sources, and auxiliary reactant sources that may be used to accomplish the goal of selectively and in coordinated manner feeding gases into reaction chamber 302. Further, as a schematic representation of a substrate processing assembly 300, many components have been omitted for simplicity of illustration, and such components may include, for example, various valves, manifolds, purifiers, heaters, containers, vents, and/or bypasses.

During operation of substrate processing assembly 300, substrates, such as semiconductor wafers (not illustrated), are transferred from, a substrate handling system to reaction chamber 302. Once substrate(s) are transferred to reaction chamber 302, one or more gases from gas sources, such as precursors, other optional reactants, carrier gases, and/or purge gases, are introduced into reaction chamber 302.

The example embodiments of the disclosure described above do not limit the scope of the invention, since these embodiments are merely examples of the embodiments of the invention, which is defined by the appended claims and their legal equivalents. Any equivalent embodiments are intended to be within the scope of this invention. Various modifications of the disclosure, in addition to those shown and described herein, such as alternative useful combinations of the elements described, may become apparent to those skilled in the art from the description. Such modifications and embodiments are also intended to fall within the scope of the appended claims.

1. A method of depositing carbon material on a substrate, the method comprising
providing a substrate in a reaction chamber;
depositing material comprising metal and carbon conformally on the substrate; and
providing a halogen compound comprising a halogen and a non-halogen element into the reaction chamber in a vapor phase to substantially remove the metal from the material comprising metal and carbon to form carbon material comprising at least 75 at-% carbon on the substrate.

2. The method of claim 1, wherein the material comprising metal and carbon is deposited by a cyclic deposition process.

3. The method of claim 2, wherein the material comprising metal and carbon comprises a carbide.

4. The method of claim 1, wherein a metal in the material comprising metal and carbon is a transition metal.

5. The method of claim 1, wherein the metal in the material comprising metal and carbon is selected from aluminum, titanium, iron, cobalt, nickel, niobium, molybdenum, hafnium, tantalum and tungsten.

6. The method of claim 1, wherein the material comprising metal and carbon is selected from a group consisting of AlCₓ, TiCₓ, TiAlₓC_{y}, FeCₓ, CoCₓ, NiCₓ, NbCₓ, MoCₓ, HfAlₓC_{y}, TaCₓ and WCₓ.

7. The method of claim 1, wherein the non-halogen element is selected from carbon, nitrogen, boron, phosphorus and sulfur.

8. The method of claim 1, wherein the halogen compound is an organic halide.

9. The method of claim 8, wherein the organic halide has a formula CₙH_{y}XₐY_{b}, wherein X and Y are independently selected from Cl, Br and I, n is 1, 2 or 3, y+a+b is 2n or 2n+2, and wherein at least one of a and b is 1 or more.

10. The method of claim 9, wherein the organic halide is selected from CBrCl₃, CCl₄, CBr₂I₂, CCl₃I, C₂Cl₆, C₂Cl₄, C₂Cl₃Br₃, CCl₂Br₂ and CCl₂I₂.

11. The method of claim 8, wherein the organic halide is an acyl halide.

12. The method of claim 11, wherein the acyl halide is selected from a group consisting of acetyl chloride, succinyl chloride, fumaryl chloride, malonyl chloride, benzoyl chloride, terephthaloyl chloride, acetyl fluoride, succinyl fluoride, fumaryl fluoride, malonyl fluoride, terephthaloyl fluoride and benzoyl fluoride.

13. A method of depositing carbon material on a substrate, wherein the method comprises
providing a substrate in a reaction chamber;
performing a cyclic process comprising a super-cycle, the super-cycle comprising
a deposition sub-cycle comprising providing a first precursor comprising a metal into the reaction chamber in a vapor phase and providing a second precursor into the reaction chamber in a vapor phase to deposit material comprising metal and carbon conformally on the substrate; and
an etching sub-cycle comprising providing a halogen compound comprising halogen and a non-halogen element into the reaction chamber in a vapor phase to substantially remove the metal from the material comprising metal and carbon to form metal material comprising at least 75 at-% carbon on the substrate.

14. The method of claim 13, wherein the deposition sub-cycle is performed at least twice before performing the etching sub-cycle.

15. The method of claim 13, wherein the super-cycle is performed at least twice.

16. The method of claim 13, wherein the first precursor and the second precursor are provided into the reaction chamber alternately and sequentially.

17. The method of claim 1, wherein the carbon material comprises at least 95 at-% carbon.

18. The method of claim 1, wherein the carbon material comprises less than 15 at-% hydrogen.

19. The method of claim 1, wherein the carbon material displays graphitic-type hybridization and diamond-like sp³ hybridization.

20. A method of forming doped carbon material on a substrate, the method comprising
providing a substrate in a reaction chamber;
depositing material comprising metal and carbon conformally on the substrate; and
providing a halogen compound comprising a halogen and a second element into the reaction chamber in a vapor phase to substantially remove the metal from the material comprising metal and carbon to form carbon material comprising at least 75 at-% carbon and the second element on the substrate, wherein the second element is selected from nitrogen, boron, phosphorus and sulfur.
